(19) United States
(12) Patent Application Publication
(10) Pub. No.: US 2008/0054381 A1
(43) Pub. Date: Mar. 6, 2008

(54) GATE ELECTRODE OF SEMICONDUCTOR DEVICE AND METHOD OF FORMING SAME

(76) Inventor: Dong-Ki Jeon, Seoul (KR)

Correspondence Address: SHERR & NOURSE, PLLC, 620 HERNDON PARKWAY, SUITE 200, HERNDON, VA, 20170, US

(21) Appl. No.: 11/844,737

(22) Filed: Aug. 24, 2007

(30) Foreign Application Priority Data
Aug. 29, 2006 (KR) 10-2006-0082226

(51) Int. Cl. H01L 29/49; H01L 21/3205

(52) U.S. Cl. 257/413; 438/592; 257/E29.154; 257/E21.294

(57) ABSTRACT

A method of forming a gate electrode of a semiconductor device includes at least one of the following steps: Forming a gate oxide layer over a wafer substrate. Forming a polysilicon layer over the gate oxide layer. Forming a TiSiN layer over the polysilicon layer. Forming a WSix layer over the TiSiN layer.

This patent application claims priority under 35 U.S.C. 119 to Korean Patent Application No. 10-2006-0082226, filed on Aug. 29, 2006, which is hereby incorporated by reference in its entirety.

### BACKGROUND

In a MOS semiconductor device, the gate electrode may have a polycide structure. A polycide structure may be patterned in a line through exposure and etch processes after doped polysilicon (e.g. a polysilicon layer) and silicide are sequentially laminated on and/or over a gate oxide layer. A silicide layer may be formed to minimize resistivity of and line resistance of a gate electrode.

Materials used in a silicide layer may includes tungsten silicide (WSix). A silicide layer may be formed by Chemical Vapor Deposition (CVD) using WF6 and SiH4 or WF6 and SiH4Cl as reaction gases. Fluorine (F) may be generated from the reaction gas WF6 during a WSix formation reaction. Fluorine (F) may infiltrate up to the underlying gate oxide layer along a grain boundary of the polysilicon. Infiltrated fluorine (F) may breaks Si—O coupling at the interface of a gate oxide (SiO2) layer and a silicon substrate and/or may increase the thickness of a gate oxide layer. Infiltrated fluorine (F) may cause several device characteristic problems, such as the migration of the threshold voltage or a reduction in the saturation current.

A method may form a TiN layer as an anti-diffusion film between a WSix layer and a polysilicon layer, in the range from about 150 Å to about 1500 Å by reactive sputtering. The TiN layer may have a columnar structure. Forming a TiN layer by reactive sputtering may have the drawback that the TiN layer having a columnar structure and the interface between columns may serve as the diffusion path of fluorine (F), thereby limiting diffusion prevention of fluorine (F).

### SUMMARY

Embodiments relate to a Metal-Oxide-Silicon (MOS) semiconductor device with a gate electrode having a polycide structure and a method of forming the gate electrode. Embodiments provide a method of forming a polycide gate electrode structure in which an amorphous TiSiN layer is formed between a polysilicon layer and a WSix layer to prevent fluorine (F) diffusion.

In embodiments, a method of forming a gate electrode of a semiconductor device includes at least one of the following steps: Forming a gate oxide layer over a wafer substrate. Forming a polysilicon layer over the gate oxide layer. Forming a TiSiN layer over the polysilicon layer. Forming a WSix layer over the TiSiN layer.

In embodiments, a gate electrode of a semiconductor device may have a laminated structure in which a gate oxide layer, a polysilicon layer, and a WSix layer are sequentially laminated over a wafer substrate, with a TiSiN layer formed between the polysilicon layer and the WSix layer.

### DRAWINGS

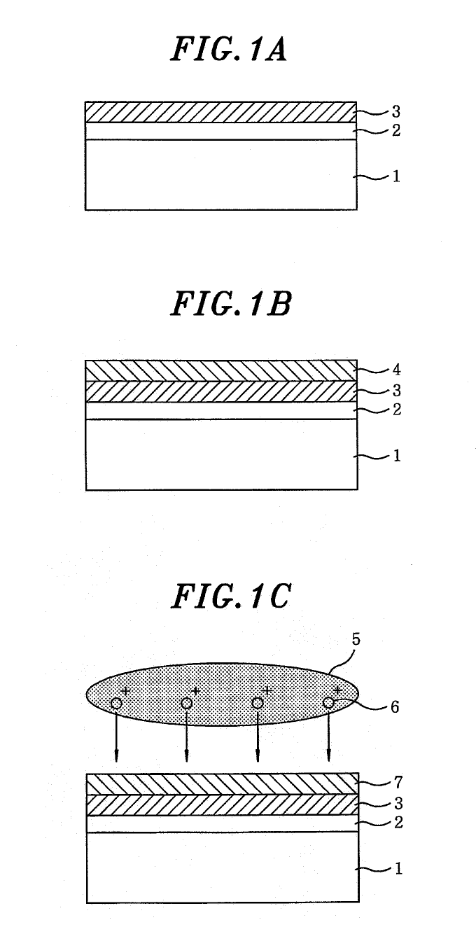

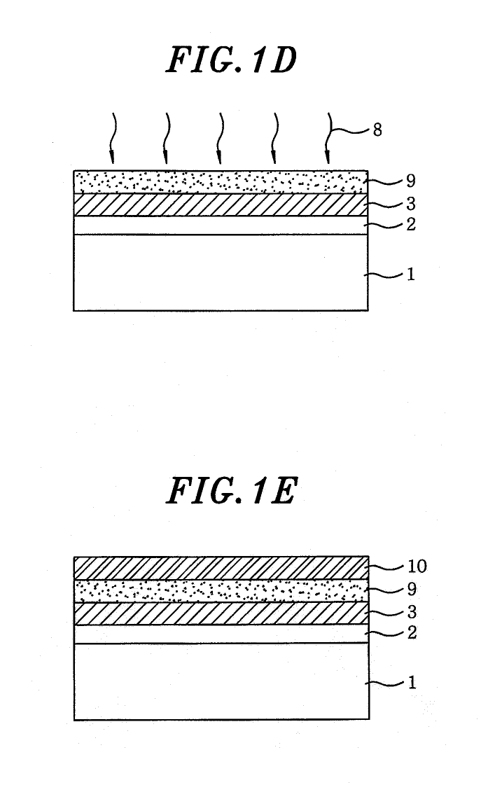

Example FIGS. 1A to 1E illustrate a method of forming a gate electrode of a semiconductor device, in accordance with embodiments.

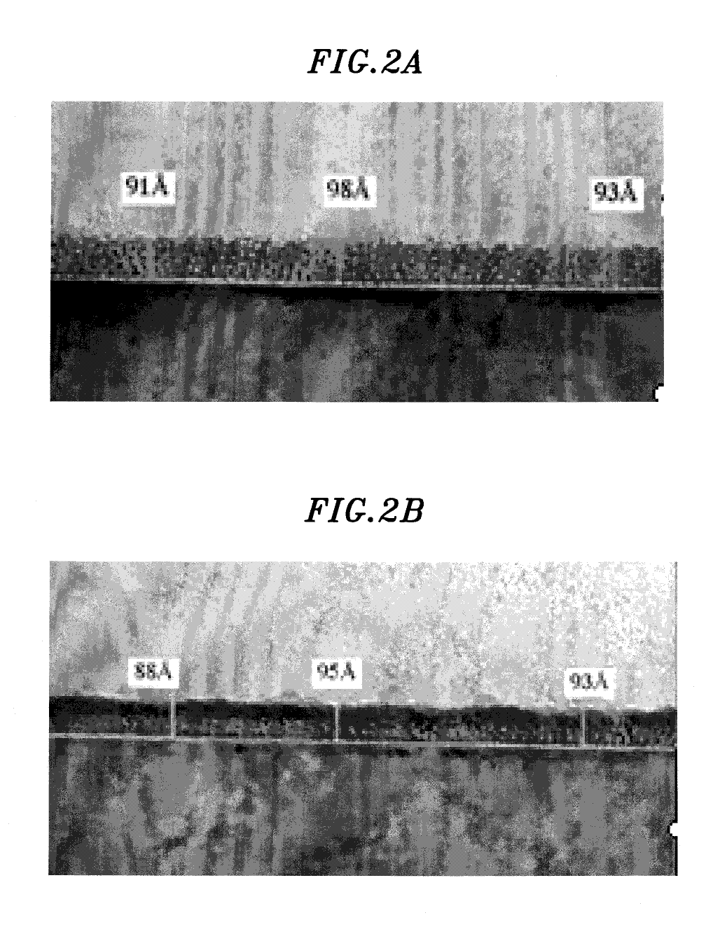

Example FIGS. 2A and 2B are TEM photographs of variations in the micro tissue of a TiN layer before and after the spray of SiH4, in accordance with embodiments.

### DESCRIPTION

As illustrated in example FIG. 1A, gate oxide layer 2 may be formed over silicon wafer 1, in accordance with embodiments. Polysilicon layer 3 may be formed over gate oxide layer 2. As illustrated in example FIG. 1B, TiN layer 4 may be formed over polysilicon layer 3. TiN layer 4 may be formed from Tetra Dimethyl Amino Titanium (DMAT) that is introduced into a chamber and thermally decomposed over the wafer. In embodiments, the wafer may be maintained at a temperature range between about 300° C. and about 500° C. and a working pressure within the chamber may be maintained between a range from about 1 Torr to about 10 Torr. TiN layer 4 may have an amorphous structure, in accordance with embodiments. A TiN layer may include Carbon, Oxygen, or other similar material caused by TDMAT (Tetra Dimethyl Amino Titanium), which may contribute to high resistivity.

As illustrated in example FIG. 1C, in order to remove the impurities (e.g. Carbon and/or Oxygen), a plasma treatment may be performed on TiN layer 4 to form plasma treated TiN layer 7, in accordance with embodiments. A plasma treatment may use H2/N2 gas plasma 5. In a plasma treatment, H2/N2 gas plasma is made and a negative bias is applied to the wafer, so that positive ions 6 (e.g. H+ and N2+ within the plasma) are projected into TiN layer 4. The incident ions may have a high kinetic energy. As these ions collide against the TiN layer, the amount of the impurities (e.g. Carbon and/or Oxygen) within the TiN layer may be reduced, which may reduce the resistivity of the TiN layer. In embodiments, the power applied to generate and maintain the plasma may be between approximately 500 W and approximately 1000 W.

In embodiments, an amorphous micro tissue may shift to crystalline TiN having a micro grain boundary due to the plasma treatment process. In embodiments, a TiN layer may be formed by Metal Organic Chemical Vapor Deposition (MOCVD). In embodiments, a thermal decomposition process of TDMAT and H2/N2 plasma treatment may be repeated a plurality of times. The thickness of a TiN layer may be increased according to the number times a thermal decomposition process and a plasma treatment are performed. For example, a TiN layer may have a thickness of approximately 30 Å when a thermal decomposition/plasma treatment is performed one time, while the thickness may be 60 Å if the thermal decomposition/plasma treatment is performed two times. The thickness of a TiN layer may be between approximately 30 Å and approximately 500 Å, in accordance with embodiments.

As illustrated in example FIG. 1D, a SiH4 gas 8 is sprayed on plasma-treated TiN layer 7 to form TiSiN layer 9, in accordance with embodiments. A wafer may be maintained at a temperature between approximately 300° C. and approximately 500° C., in accordance with embodiments. A SiH4 gas may be sprayed at the flow rate between approximately 10 sccm and approximately 5000 sccm for about 20 to 360 seconds, in accordance with embodiments. If the working pressure within the chamber is too low, TiSiN may not be generated effectively. If the working pressure within the chamber is too high, undesirable particles may be generated. Accordingly, the pressure of the chamber may be maintained between approximately 0.1 Torr and approximately 10 Torr.

During the formation of TiSiN layer 9, the entire TiN layer 7 may be converted to TiSiN layer (e.g. based on the spray conditions of SiH4), in accordance with embodiments. In embodiments, only a portion of TiN layer 7 may be converted to TiSiN (e.g. an upper portion). TiSiN layer 9 may have a thickness between approximately 30 Å and approximately 500 Å. In embodiments, the thickness of TiSiN layer 9 may be approximately the same as the thickness of TiN layer 7 before SiH4 is sprayed. TiSiN layer 9 may have an amorphous structure, which does not have a grain boundary, in accordance with embodiments. An amorphous structure without a grain boundary may prevent and/or minimize diffusion path for fluorine (F) to be formed (e.g. TiSiN layer 9 may have a relatively good diffusion prevention ability), in accordance with embodiments.

Example FIGS. 2A and 2B are TEM photographs of a MOCVD TiN before and after the spray of SiH4, in accordance with embodiments. Example FIG. 2A is a photograph of a micro-crystalline TiN before SiH4 is sprayed. Example FIG. 2B is a photograph of amorphous TiSiN (the black part) on an upper portion of a TiN layer after SiH4 is sprayed.

As illustrated in example FIG. 1E, WSix 10 may deposited by a CVD method using WF6 gas and SiH4 gas, in accordance with embodiments.

In embodiments, a TiSiN layer may be formed over a polysilicon layer, fluorine (F) generated when depositing WSix may be prevented and/or minimized from infiltrating into a gate oxide layer. Accordingly, it may be possible to prevent and/or minimize degradation of a gate oxide layer due to fluorine (F), in accordance with embodiments.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising:
forming a gate oxide layer over a wafer substrate;
forming a polysilicon layer over the gate oxide layer;
forming a TiSiN layer over the polysilicon layer; and
forming a WSix layer over the TiSiN layer.

2. The method of claim 1, wherein the method is a method of forming a gate electrode in a semiconductor device,

3. The method of claim 1, wherein the TiSiN layer is an amorphous layer.

4. The method of claim 1, wherein said forming the TiSiN layer comprises forming a TiN layer.

5. The method of claim 4, wherein said forming the TiN layer comprises thermally decomposing a Tetra Dimethyl Amino Titanium (TDMAT) source.

6. The method of claim 4, wherein said forming the TiSiN layer comprises performing plasma treatment on the TiN layer to form a plasma-treated TiN layer.

7. The method of claim 6, wherein the plasma treatment employs a N2 and H2 plasma.

8. The method of claim 6, wherein said forming the TiSiN layer comprises spraying a SiH4 gas onto the plasma-treated TiN layer.

9. The method of claim 8, wherein said spraying the SiH4 gas is performed at a temperature of the wafer substrate between approximately 300° C. and approximately 500° C. and the working pressure is between approximately 0.1 Torr and approximately 10 Torr.

10. The method of claim 1, wherein the TiSiN layer has a thickness between approximately 30 Å and approximately 500 Å.

11. A apparatus comprising:
a gate oxide layer formed over a wafer substrate;
a polysilicon layer formed over the gate oxide layer;
a TiSiN layer formed over the polysilicon layer; and
a WSix layer formed over the TiSiN layer.

12. The apparatus of claim 11, wherein the apparatus comprises a gate electrode in a semiconductor device.

13. The apparatus of claim 11, wherein the TiSiN layer is an amorphous layer.

14. The apparatus of claim 11, wherein the TiSiN layer is formed from a TiN layer.

15. The apparatus of claim 14, wherein the TiN layer is formed by thermally decomposing a Tetra Dimethyl Amino Titanium (TDMAT) source.

16. The apparatus of claim 14, wherein the TiSiN layer is formed by performing plasma treatment on the TiN layer to form a plasma-treated TiN layer.

17. The apparatus of claim 16, wherein the plasma treatment employs a N2 and H2 plasma.

18. The apparatus of claim 16, wherein the TiSiN layer is formed by spraying a SiH4 gas onto the plasma-treated TiN layer.

19. The apparatus of claim 18, wherein said spraying the SiH4 gas is performed at a temperature of the wafer substrate between approximately 300° C. and approximately 500° C. and the working pressure is between approximately 0.1 Torr and approximately 10 Torr.

20. The apparatus of claim 11, wherein the TiSiN layer has a thickness between approximately 30 Å and approximately 500 Å.
